(19) United States
(12) Patent Application Publication
(10) Pub. No.: US 2012/0052260 A1
(43) Pub. Date: Mar. 1, 2012

(54) STRUCTURE MANUFACTURING METHOD AND STRUCTURE

(75) Inventor: Shin Masuhara, Tokyo (JP)

(73) Assignee: Sony Corporation, Tokyo (JP)

(21) Appl. No.: 13/212,520

(22) Filed: Aug. 18, 2011

(30) Foreign Application Priority Data
Aug. 25, 2010 (JP) 2010-188272

(51) Int. Cl. B32B 3/00; G03F 7/20

(52) U.S. Cl. 428/195.1; 430/325

(57) ABSTRACT

A structure manufacturing method includes laminating a first film on a base material, selectively irradiating the first film with an energy ray depending on a position of a surface of the first film on the base material, to form a latent image of a pattern on the first film, laminating a second film on the surface of the first film, and supplying a developer to the second film and removing a removal target portion of the first film to be selectively removed along with the second film, thereby developing the pattern.

### BACKGROUND

The present disclosure relates to a method of manufacturing a three-dimensional structure by laminating film-formed materials and to a structure.

In a stereolithography process of a laminating type, for example, there is a liquid surface regulation method, in which light curable resin is used, and while regulating a liquid surface of the resin liquid with a glass plate for each layer, the liquid surface is irradiated with light through the glass plate, thereby forming a modeled object having a highly accurate film thickness.

In actuality, however, as the area (area viewed in a planar direction) of a modeled object is increased, the amount of contraction of light curable resin in a thickness direction due to the curing becomes large, which causes a problem in that a film thickness distribution of about several tens of percent is caused in plane depending on kinds of resin. Further, there arises a problem in that the adhesion between the cured resin and a glass plate is strong due to the contraction of the resin, and therefore it is difficult to perform a process (releasing process) for peeling the cured resin from the glass plate for the liquid surface regulation.

In view of this, a film lamination method is proposed in which photosensitive materials each formed into a film shape are laminated to model an object. In the film lamination method, the use of the film material eliminates the necessity of regulation of the liquid surface. Thus, the aforementioned problems are not caused. In addition, the handling of the film material is easier than the liquid material, and the amount of use of cleaner is significantly reduced, which is advantageous in terms of safety and health.

It should be noted that, for example, Japanese Patent Application Laid-open No. Hei 7-227909 discloses a modeling method of laminating a photosensitive film material.

### SUMMARY

Incidentally, after exposure of the resin material, it is necessary to remove a non-exposure portion (in the case of negative type) to perform development. In the case where the resin material is liquid, a portion to be removed (hereinafter, referred to as removal target portion) is easily removed with a cleaner. In the film lamination method, however, since the film material is solid or semisolid, there is a problem in that the removal target portion is difficult to be removed.

In particular, it is difficult to remove the removal target portion in a groove or a hole having a narrow width and a high aspect ratio. In this case, there is a method of manually pressing an adhesive tape to a modeled object in order to remove the removal target portion which remains in the groove or the hole. However, by this method, the adhesive tape leaves a mark. Further, the manual operation is performed, which results in poor productivity.

In view of the above-mentioned circumstances, it is desirable to provide a structure manufacturing method having a technique capable of easily removing the removal target portion of the film after selective irradiation with an energy ray in the film lamination method, and provide a structure manufactured by the structure manufacturing method.

According to an embodiment of the present disclosure, there is provided a structure manufacturing method including laminating a first film on a base material.

The first film is selectively irradiated with an energy ray depending on a position of a surface of the first film on the base material, to form a latent image of a pattern on the first film.

A second film is laminated on the surface of the first film.

A developer is supplied to the second film, and a removal target portion of the first film to be selectively removed is removed along with the second film, thereby developing the pattern.

By supplying the developer to the second film, the removal target portion of the first film is swollen along with the second film, so the removal target portion swollen is easily removed along with the second film. As a result, a highly accurate pattern can be formed.

The laminating the first film on the base material may be repeated by using a plurality of first films one by one. In this case, the developing is performed collectively for the plurality of first films after at least the first film laminated at an end is irradiated with the energy ray. As a result, it is unnecessary to develop the plurality of first films one by one, which can significantly reduce a manufacturing time period. The plurality of first films may be collectively irradiated with the energy ray or may be irradiated with the energy ray one by one.

The first film and the second film may be made of the same material. With this structure, it is unnecessary to use films made of different materials for the first film and the second film, with the result that the cost can be cut. Further, in the case where a manufacturing apparatus that uses the manufacturing method is achieved, only one supply mechanism of the films is used, so it is possible to simplify the structure of the manufacturing apparatus.

The structure manufacturing method may further include performing pressure defoaming of the first film and the second film on the base material after the laminating the second film and before the developing. As a result, the adhesion between the second film and the first film thereunder is increased, and the films are further integrated physically (mechanically), thereby making it easier to integrally remove both the films in the developing.

According to another embodiment of the present disclosure, there is provided a structure manufactured by the manufacturing method described above.

As described above, according to the embodiments of the present disclosure, in the film lamination method, it is possible to easily remove the removal target portion of the film after being selectively irradiated with the energy ray.

These and other objects, features and advantages of the present disclosure will become more apparent in light of the following detailed description of best mode embodiments thereof, as illustrated in the accompanying drawings.

### BRIEF DESCRIPTION OF DRAWINGS

FIGS. 1 are diagrams showing a method of manufacturing a structure (including a modeled object) in sequential order according to an embodiment of the present disclosure; FIGS. 2 are diagrams showing the manufacturing method subsequent to the process shown in FIGS. 1;

FIG. 3 is a photograph showing a result of an improvement in resolution by the manufacturing method of the structure according to this embodiment, and is a planar photograph of the structure in which a resolution test chart is formed;

FIG. 4 is a planar photograph of a structure manufactured by a manufacturing method to be compared thereto; and

FIGS. 5 are diagrams showing the manufacturing method to be compared in sequential order.

### DETAILED DESCRIPTION OF EMBODIMENTS

Hereinafter, an embodiment of the present disclosure will be described with reference to the drawings.

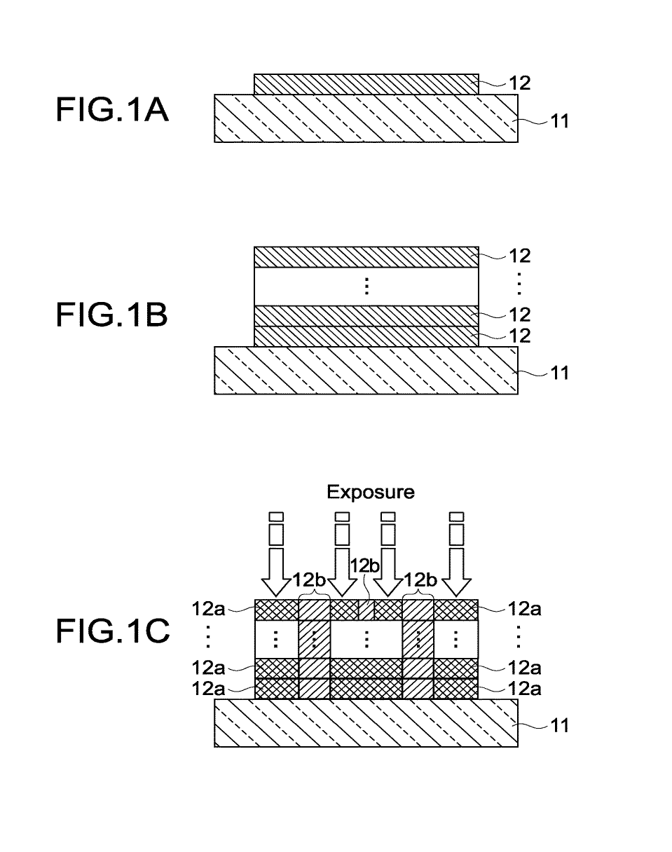

FIGS. 1 and 2 are diagrams showing a method of manufacturing a structure (including a modeled object) in sequential order.

The structure is typically used as a microfluidic chip, and can also be used as an MEMS (micro electro mechanical systems) structure or another structure.

As a base material, a glass substrate 11 is prepared, for example. In addition to the glass substrate 11, the base material may be a substrate made of metal, resin, or the like.

As shown in FIG. 1A, a film (first film) 12 on which a latent image of a pattern is formed in response to an energy ray is laminated on the glass substrate 11. Hereinafter, the film is referred to as a pattern film for convenience of explanation. A thickness of the pattern film 12 is, for example, 10 to 30 μm, typically, 20 μm, but is not limited to this range.

The energy ray means a ray having an energy quantum out of an electromagnetic wave and a charged particle radiation, including an infrared ray, an ultraviolet ray, visible light, or an electron beam, for example. In the following description, a mode in which an ultraviolet ray is used as the energy ray is explained.

The pattern film 12 is made of a polymer material (UV curable resin) that is cured (cross-linked) by being irradiated with the UV ray. For example, as the pattern film 12, a “UV curable polymer material” disclosed in Japanese Patent Application Laid-open No. 2009-180880 is used. The pattern film 12 is laminated on the glass substrate 11 by being transferred, for example. For the pattern film 12, a semisolid, gelled material may be used.

Before the pattern film 12 is laminated on the glass substrate 11, another film (different from the pattern film 12) or a coated film (not shown) may be formed as a base layer on the surface of the glass substrate 11. The base layer is used to increase the adhesion between the glass substrate 11 and the pattern film 12 through the base layer.

The laminating process of the pattern film 12 shown in FIGS. 1A is repeated, thereby laminating the pattern films 12 as shown in FIG. 1B. The number of pattern films 12 is appropriately set in accordance with the shape of the structure to be formed, and is approximately 5 to 10, for example. However, the pattern film 12 may not be necessarily laminated. Only one pattern film 12 (single layer) may be used.

As shown in FIG. 1C, to form a predetermined pattern on the pattern films 12 laminated, selective irradiation with the UV ray is performed depending on a surface position of the pattern film 12, and a plurality of pattern films 12 are collectively exposed. A cured portion 12a is formed as a part which is irradiated with the UV ray, and an uncured portion 12b is formed as a non-exposure part. In the example shown in the figure, two deep groove portions and one shallow groove portion are formed as the uncured portions 12b. The pattern is just an example for ease of explanation, and various patterns may be formed. As a method of irradiation with the UV ray, a method of scanning with laser light or a method of using a mask may be used.

In the exposure process in this embodiment, it is possible to appropriately adjust the depth of irradiation with the UV ray in accordance with the shape of the pattern to be formed. The exposure process may be separately performed more than once as follows.

That is, in FIG. 1B, the pattern films 12 are laminated and exposed collectively, but the exposure may be performed for each of at least one pattern film 12 depending on the shape of the pattern of the structure or accuracy of the shape of the structure to be demanded.

For example, the exposure process for an uppermost pattern film 12 shown in FIG. 1C and the exposure process for a plurality of pattern films 12 thereunder may be performed in separate processes. Thus, as shown in FIG. 1C, it is possible to make the pattern formed on the uppermost pattern film 12 different from the pattern formed on the plurality of lower pattern films 12.

After the process of FIG. 1B, to prevent oxygen inhibition, a protection layer may be formed on the uppermost pattern film 12 before the process of FIG. 1C. The protection layer is formed by applying a protection material or laminating a protection film. In the case where the protection layer is formed, the irradiation with the UV ray is performed from above the protection layer. An example of a harmful effect of the oxygen inhibition will be given. If the pattern film 12 is subjected to the exposure process while being exposed to oxygen, the exposure process of the surface of the pattern film 12 may be delayed or may be difficult to be carried out due to oxygen in the pattern film 12. The protection layer is peeled off after the exposure process and before the process of FIG. 2A.

As the protection layer, for example, a polycarbonate sheet which is excellent in optical characteristics, film thickness accuracy, and smoothness. The polycarbonate sheet has those advantageous characteristics, and therefore also has a function as a regulation body in the liquid surface regulation method of the modeling process. Further, the polycarbonate is easily peeled off from the uppermost pattern film 12.

Instead of providing the protection layer, the exposure may be carried out in a low oxygen atmosphere. The low oxygen atmosphere is attained in a vacuum or in an inert gas atmosphere, for example.

Next, as a prior process of the development process, as shown in FIG. 2A, a film (second film) 12′ is laminated on the surface of the uppermost pattern film 12. The film which is laminated in the prior process of the development process is referred to as a development film in the following description for convenience. For the development film 12′, the same material as the pattern film 12 is used typically. On the development film 12′, a pattern is not formed. That is, the exposure is not carried out. Because the pattern film 12 and the development film 12′ are made of the same material, there is no need to use different kinds of films, which reduces the cost. Further, in the case where a manufacturing apparatus using the manufacturing method is achieved, only one film supply mechanism is used, which can simplify the structure of the manufacturing apparatus.

However, the pattern film 12 and the development film 12′ may not be made of the same material. For example, a material which is more likely to react to a developer as compared to the material of the pattern film 12 may be applied to the development film 12′ as will be described later.

Next, as shown in FIGS. 2B and 2C, the development process is performed. Specifically, a developer such as ethanol is supplied onto at least the development film 12′. Although ethanol is used as the developer, toluene, methanol, acetone, or the like may be used depending on the material of the pattern film 12 and the development film 12′. As a development method, a dip type, a paddle type, a spray type, or any other type may be used.

A development time period is set to approximately 2 to 10 minutes, for example, and is appropriately set mainly in accordance with the number of pattern films 12 to be used.

By supplying the developer, the removal target portion (uncured portion 12b) of the pattern film 12 as a target to be selectively removed and the development film 12′, which is substantially entirely uncured, are integrally swollen and clouded. That is, the development film 12′ functions as a peeling layer.

The pattern film 12 and the development film 12′ may be made of different materials as described above, as long as the development film 12′ and the uncured portion 12b of the pattern film 12 are integrally swollen to some extent.

As shown in FIG. 2C, a portion that has been swollen (swollen portion) 12″ is removed. The swollen portion 12″ is naturally removed during the development shown in FIG. 2C substantially. Therefore, there is no need to carry out a gas blow, an ultrasonic cleaning, or a removal process with a cleaning solution or the like to remove the swollen portion 12″. As a result, it is possible to reduce a process time period.

In related art, the uncured portion is removed by an air blow after the development. In this embodiment, this process is not necessary, with the result that the process time period can be reduced.

Further, because there is no need to carry out the cleaning process or the air blow process, a physical shock is not applied to the target object. Therefore, there is no possibility of causing peeling or the like on an interface between the pattern films 12 (in the case of a multilayered manner) and on an interface between the glass substrate 11 and the pattern film 12.

In this embodiment, even in the case where the ultrasonic cleaning is carried out, it takes a shorter time (1 to 2 minutes) as compared to the case in the related art.

As described above, in the manufacturing method according to this embodiment, by supplying the developer to the development film 12″, the removal target portion (uncured portion 12b) of the pattern film 12 is swollen along with the development film 12′, so the removal target portion is easily removed along with the development film 12′. As a result, a highly accurate pattern can be formed. In particular, there is no need to adhere the adhesive tape to the part difficult to be removed and peel off the part, so it is possible to prevent the adhesive tape from leaving its mark on the surface (surface of the uppermost pattern film 12) of the structure. In addition, according to this embodiment, it is possible to remove the removal target portion more neatly as compared to the case where the adhesive tape is used. Further, in the manufacturing method according to this embodiment, the adhesive tape is unnecessary, so the processes are easily automated, which improves productivity.

In this embodiment, after the process of FIG. 1C, as shown in FIGS. 2A to 2C, the plurality of pattern films 12 are subjected to the pattern latent image process (exposure process), and then the plurality of pattern films 12 are subjected to the collective development. Thus, it is unnecessary to develop the pattern films 12 one by one, with the result that it is possible to significantly reduce the manufacturing time period.

After the process shown in FIG. 2A, before the development process of FIGS. 2B and 2C, a defoaming process may be carried out. The defoaming process is carried out by pressurization, for example. Thus, an adhesion force between the development film 12′ and the pattern films 12 thereunder is increased, with the result that the integral swelling process can be more reliably performed.

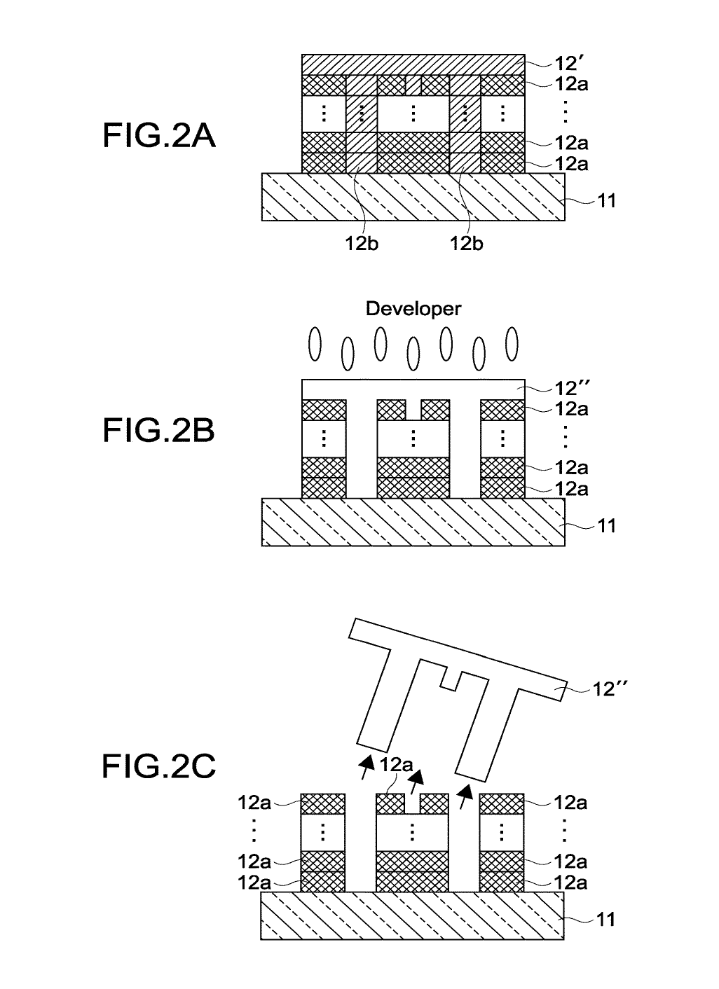

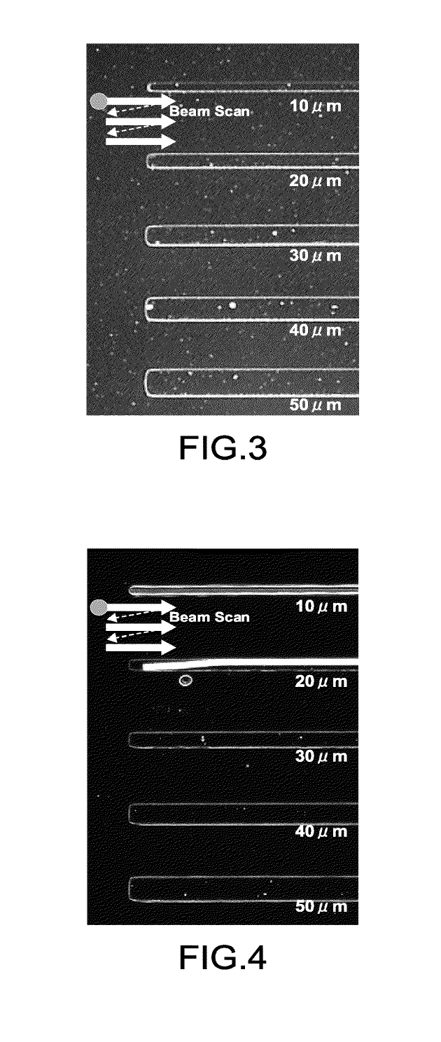

FIG. 3 is a photograph showing a result of an improvement in resolution by the manufacturing method of the structure according to this embodiment, and is a planar photograph of the structure in which a resolution test chart is formed. FIG. 4 is a photograph of a comparison target thereof. Conditions of this test will be shown in the following.

Thickness of pattern film (UV curable resin): 20 μm (not multilayer but single layer)

Thickness of development film (UV curable resin made of the same material as the pattern film 12): 20 μm (In FIG. 4, the development film is not used)

Energy ray: UV laser having wavelength of 375 nm

Spot diameter of laser beam: approximately 2 μm

Exposure type: scan with galvano mirror (NA of an objective lens is 0.1), scan speed of 120 mm/s, feed pitch of 1.0 μm, exposure output (UV ray output after exiting the objective lens) of 1.5 mW

Shape of resolution test chart: concave, linear grooves having widths of 10 μm, 20 μm, 30 μm, 40 μm, and 50 μm, respectively

Development type: ethanol as the developer, dip type for 5 minutes (only in the case of FIG. 4, the development is carried out while performing irradiation with ultrasonic waves for 20 minutes)

Protection layer (hard coat layer made of polycarbonate): with (this layer is peeled off before the development process)

High-pressure air blow for removal of uncured portion 12b: with only in the case of FIG. 4

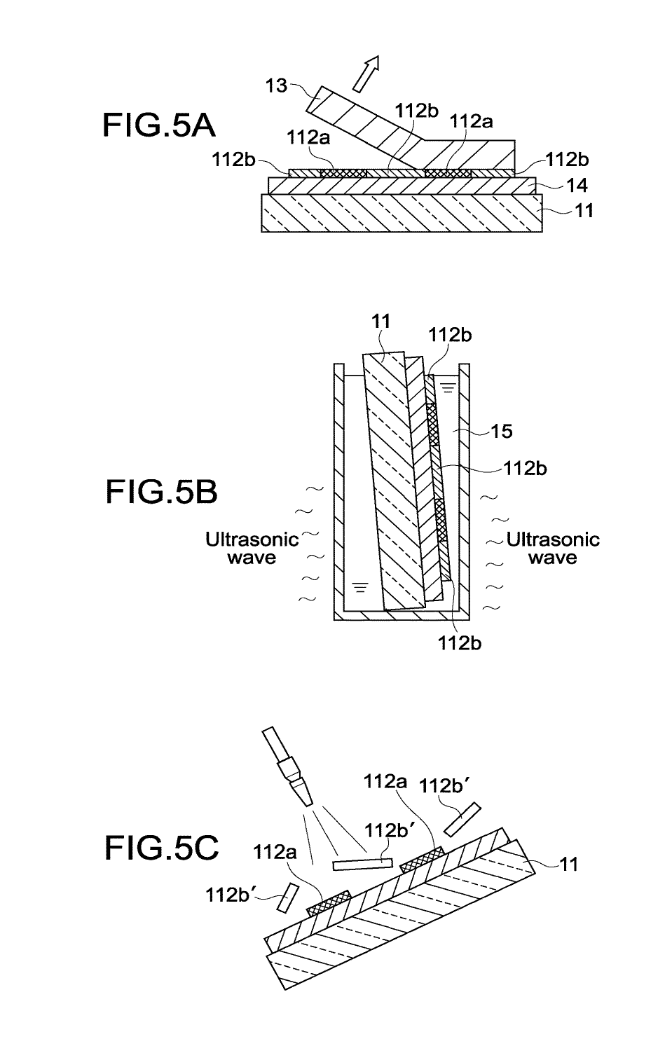

In this test, FIG. 3 shows the result of the development of the inside of the groove as the uncured portion 12b by the manufacturing method according to this embodiment, and FIG. 4 shows the result of the development by a development method to be compared. The development method to be compared is a method as shown in FIGS. 5, for example.

As shown in FIG. 5A, cured portions 112a and uncured portions 112b are formed by an exposure process with the UV ray, and then the protection layer 13 made of polycarbonate is peeled off. As shown in FIG. 5B, a target object is immersed in an ethanol 15, and thus the uncured portions 112b are swollen. As shown in FIG. 5C, uncured portions 112b′ swollen are removed by the high-pressure air blow. It should be noted that in this example, a base layer 14 for increasing the adhesion is formed on the glass substrate 11.

In FIG. 3, the uncured portions in all the grooves having the widths of 10 to 50 μm were removed. In contrast, in FIG. 4, the uncured portions in the grooves having the widths of 10 μm and 20 μm were not removed. Thus, a superiority of the manufacturing method according to this embodiment shown in FIG. 3 was proved.

In addition, in this embodiment, the ultrasonic irradiation and the high-pressure air blow are unnecessary at the time of the development. Therefore, it is possible to make the process time period shorter as compared to the comparison method. Further, because those processes are unnecessary, a physical shock is not applied to the target object, eliminating such a possibility that peeling or the like occurs on the interface between the pattern films 12 (in the case of the multilayered manner) or the interface between the glass substrate 11 and the pattern film 12.

In addition to the test described above, the inventors of the present invention confirmed, through an experience, the depth of the grooves from which the uncured portions 12b can be removed, while changing the aspect ratio of the shape of the grooves. As a result, it was confirmed that the uncured portions 12b can be removed in the case of the aspect ratio of up to approximately 4 in the current situation.

### Another Embodiment

The present disclosure is not limited to the above embodiment, and various other embodiments can be achieved.

As the film, the negative film, which is cured by being irradiated with the energy ray, is used. A positive film, which is softened by being irradiated with the energy ray, may be used.

The present disclosure contains subject matter related to that disclosed in Japanese Priority Patent Application JP 2010-188272 filed in the Japan Patent Office on Aug. 25, 2010, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A structure manufacturing method, comprising:
laminating a first film on a base material;
selectively irradiating the first film with an energy ray depending on a position of a surface of the first film on the base material, to form a latent image of a pattern on the first film;
laminating a second film on the surface of the first film; and
supplying a developer to the second film and removing a removal target portion of the first film to be selectively removed along with the second film, thereby developing the pattern.

2. The structure manufacturing method according to claim 1, wherein
the laminating the first film on the base material is repeated by using a plurality of first films one by one, and
the developing is performed collectively for the plurality of first films after at least the first film laminated at an end is irradiated with the energy ray.

3. The structure manufacturing method according to claim 1, wherein
the first film and the second film are made of the same material.

4. The structure manufacturing method according to claim 1, further comprising
performing pressure defoaming of the first film and the second film on the base material after the laminating the second film and before the developing.

5. A structure manufactured by a manufacturing method including
laminating a first film on a base material,
selectively irradiating the first film with an energy ray depending on a position of a surface of the first film on the base material, to form a latent image of a pattern on the first film,
laminating a second film on the surface of the first film, and
supplying a developer to the second film and removing a removal target portion of the first film to be selectively removed along with the second film, thereby developing the pattern.
